(19) United States
(12) Patent Application Publication
(10) Pub. No.: US 2026/0085425 A1
(43) Pub. Date: Mar. 26, 2026

(54) PLASMA-ENHANCED CHEMICAL VAPOR DEPOSITION METHOD

(71) Applicants: Tokyo Electron Limited, Tokyo (JP); International Business Machines Corporation, Armonk, NY (US)

(72) Inventors: Devi Koty, Fishkill, NY (US); Peter Kerns, Bethel, CT (US)

(21) Appl. No.: 18/891,960

(22) Filed: Sep. 20, 2024

(51) Int. Cl. C23C 16/511; C23C 16/34; C23C 16/40; C23C 16/455; C23C 16/458; C23C 16/52; C23C 16/56

(52) U.S. Cl. CPC C23C 16/511; C23C 16/345; C23C 16/401; C23C 16/45502; C23C 16/45565; C23C 16/4558; C23C 16/4586; C23C 16/52; C23C 16/56

(57) ABSTRACT

A method for processing a substrate includes having a plasma-enhanced chemical vapor deposition (PECVD) chamber including sidewall gas inlets and a top gas inlet disposed on a top plate of the PECVD chamber. The method further includes receiving the substrate on a substrate holder disposed within the PECVD chamber, and flowing a precursor gas mixture into the PECVD chamber through the sidewall gas inlets at a first flow rate and the top gas inlet at a second flow rate. And the method further includes applying a source power to the top plate to form a plasma from the precursor gas mixture, and exposing the substrate to the plasma to deposit a dielectric layer over the substrate, the dielectric layer has an edge thickness at edges of the substrate and a center thickness in a center region of the substrate, the edge thickness is different from the center thickness.

### TECHNICAL FIELD

The present invention relates generally to a system and method for processing a substrate, and, in particular embodiments, to a system and method for plasma-enhanced chemical vapor deposition to form a variable thickness layer over the substrate.

### BACKGROUND

Three-dimensional (3D) packaging technology has become increasingly prevalent in the semiconductor industry. Through-silicon vias (TSVs) are common components of 3D packaging, allowing vertical electrical connections between stacked silicon layers. However, current TSV etching processes may over-etch at the bevel edges of substrates.

### SUMMARY

In accordance with an embodiment of this disclosure, a method for processing a substrate includes having a plasma-enhanced chemical vapor deposition (PECVD) chamber including sidewall gas inlets disposed on sidewalls of the PECVD chamber and a top gas inlet disposed on a top plate of the PECVD chamber. The method further includes receiving the substrate on a substrate holder disposed within the PECVD chamber, and flowing a precursor gas mixture into the PECVD chamber through the sidewall gas inlets at a first flow rate and the top gas inlet at a second flow rate. And the method further includes applying a source power to the top plate to form a plasma from the precursor gas mixture, and exposing the substrate to the plasma to deposit a dielectric layer over the substrate, where the dielectric layer has an edge thickness at edges of the substrate and a center thickness in a center region of the substrate, where the edge thickness is different from the center thickness.

In accordance with another embodiment of this disclosure, a method for processing a substrate includes depositing a first dielectric layer over the substrate, the first dielectric layer including a center region and an edge region, where the center region has a center thickness, where the edge region has an edge thickness, and where the center thickness is less than the edge thickness. The method further includes depositing a second dielectric layer over the first dielectric layer, where the second dielectric layer has a uniform thickness, and depositing a mask layer over the second dielectric layer. And the method further includes patterning the mask layer to form a patterned mask including a feature pattern, and etching the substrate to form feature openings according to the feature pattern.

And in accordance with yet another embodiment of this disclosure, a system for processing a substrate includes a substrate holder disposed within a plasma-enhanced chemical vapor deposition (PECVD) chamber, sidewall gas inlets disposed on sidewalls of the PECVD chamber, a top gas inlet disposed on a top plate of the PECVD chamber, a gas delivery system coupled to the sidewall gas inlets and the top gas inlet, the gas delivery system configured to supply a precursor gas mixture at controlled flow rates. The system further includes a vacuum pump coupled to the PECVD chamber through a gate valve, and a power source electrically coupled with the top plate. And the system further includes a controller coupled to the substrate holder, the sidewall gas inlets, the top gas inlet, the gas delivery system, the vacuum pump, the power source, and a memory storing instructions to be executed in the controller. The instructions, when executed, enable the controller to receive the substrate on the substrate holder, and flow the precursor gas mixture into the PECVD chamber through the sidewall gas inlets at a first flow rate and the top gas inlet at a second flow rate using the gas delivery system. The instructions, when executed further, enable the controller to apply, using the power source, a source power to the top plate to form a plasma from the precursor gas mixture. And the instructions, when executed further, enable the controller to expose the substrate to the plasma to deposit a dielectric layer over the substrate, where the dielectric layer has an edge thickness at edges of the substrate and a center thickness in a center region of the substrate, where the edge thickness is larger than the center thickness.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1F are cross-sectional views of a substrate illustrating various steps of a method of depositing a layer with variable thickness and subsequently processing the substrate in accordance with an embodiment of this disclosure;

FIG. 2 is a cross-sectional view of a substrate illustrating an alternative variable thickness deposition step which may be used in place of the step illustrated in FIG. 1B in accordance with an embodiment of this disclosure;

FIG. 3 illustrates a first plot of film thickness compared to radial distance from the center of the substrate for the layer with variable thickness and a second plot of refractive index (RI) compared to radial distance from the center of the substrate for the layer with variable thickness in accordance with an embodiment of this disclosure;

FIG. 4A is a schematic diagram of a plasma-enhanced chemical vapor deposition (PECVD) system which may be used to deposit a layer with variable thickness in accordance with an embodiment of this disclosure;

FIG. 4B is a schematic diagram of a gas shower head which may be used as a top plate of the PECVD system described in FIG. 4A in accordance with an embodiment of this disclosure;

FIG. 5 is a flowchart of a method of depositing a layer with variable thickness in accordance with an embodiment of this disclosure; and

FIG. 6 is a flowchart of a method of processing a substrate in accordance with an embodiment of this disclosure.

### DETAILED DESCRIPTION OF ILLUSTRATIVE EMBODIMENTS

Current through-silicon via (TSV) etching processes do not provide adequate protection for the substrate bevel edge, i.e., sidewall of the substrate with the bevel. This lack of protection, combined with insufficient resist and hard mask coverage at the edge, can result in excessive etching of hundreds of microns at the substrate bevel (or edge). Consequently, this leads to edge defects and significant die loss, reducing overall yield. While some approaches have attempted to use clamp rings for edge protection, these mechanical solutions can introduce their own set of defects and contribute to die loss at the substrate edge. Additionally, conventional deposition methods struggle to achieve uniform film coverage and thickness across the entire substrate surface, particularly at the bevel edge where step coverage may be desired.

The present disclosure provides a solution to these challenges by employing a modified plasma-enhanced chemical vapor deposition (PECVD) process for dielectric film deposition. In one or more embodiments, the gas distribution in the PECVD chamber is adjusted, such as by reducing or eliminating center gas injection, to achieve preferential deposition at the substrate edge. This results in an edge-thick dielectric film with significantly higher thickness at the bevel edge compared to the center and peripheral regions of the substrate. For example, the edge deposition rate can be 2.5 times higher than the center and 2 times higher than the donut region, resulting in a film thickness of approximately 1000 Å at the bevel edge while maintaining 300 Å at the substrate center. The thicker film at the edge provides enhanced protection during subsequent TSV etching processes, effectively preventing excessive edge etching and related defects. Furthermore, this approach may be implemented without mechanical clamping solutions like clamp rings, potentially increasing overall yield and reducing edge-related defects which may result from using clamp rings. The method also achieves improved step coverage at the bevel edge, with coverage rates exceeding 70% in some embodiments, ensuring more consistent and reliable TSV processing across the entire substrate surface.

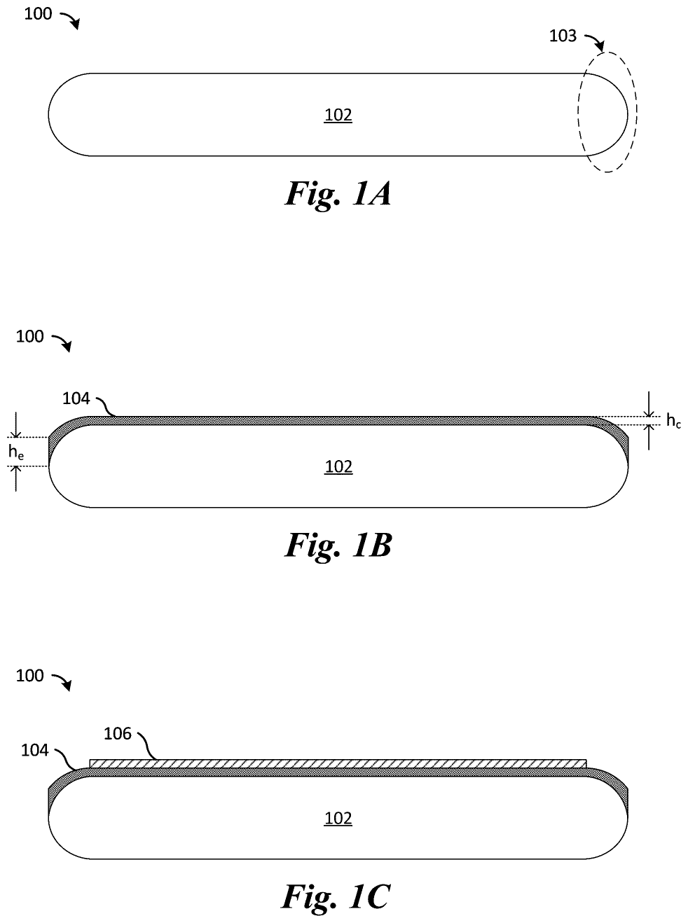

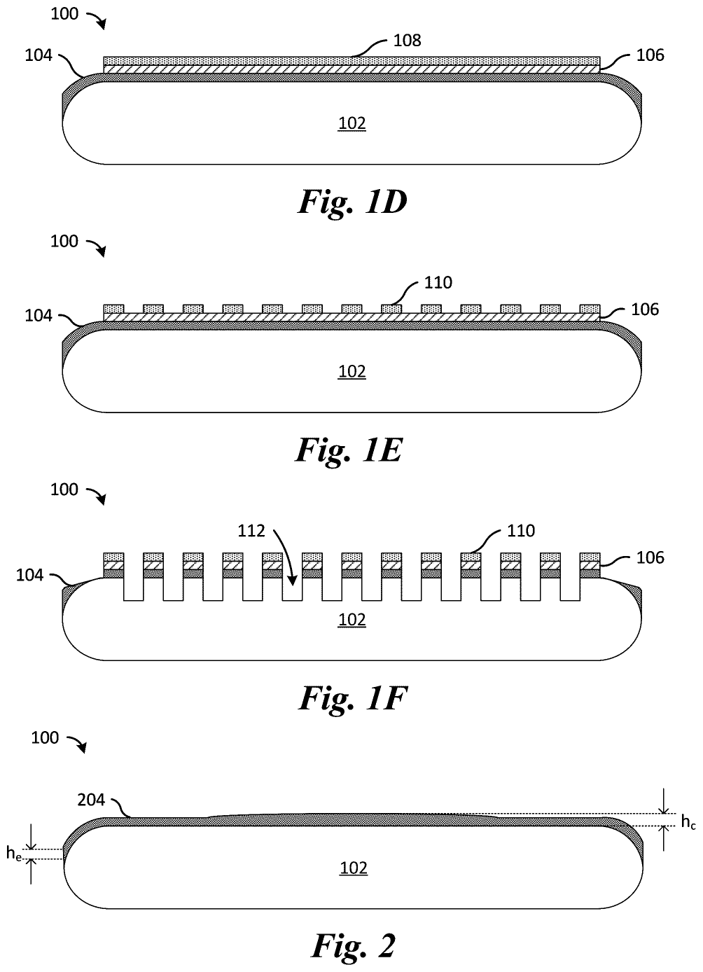

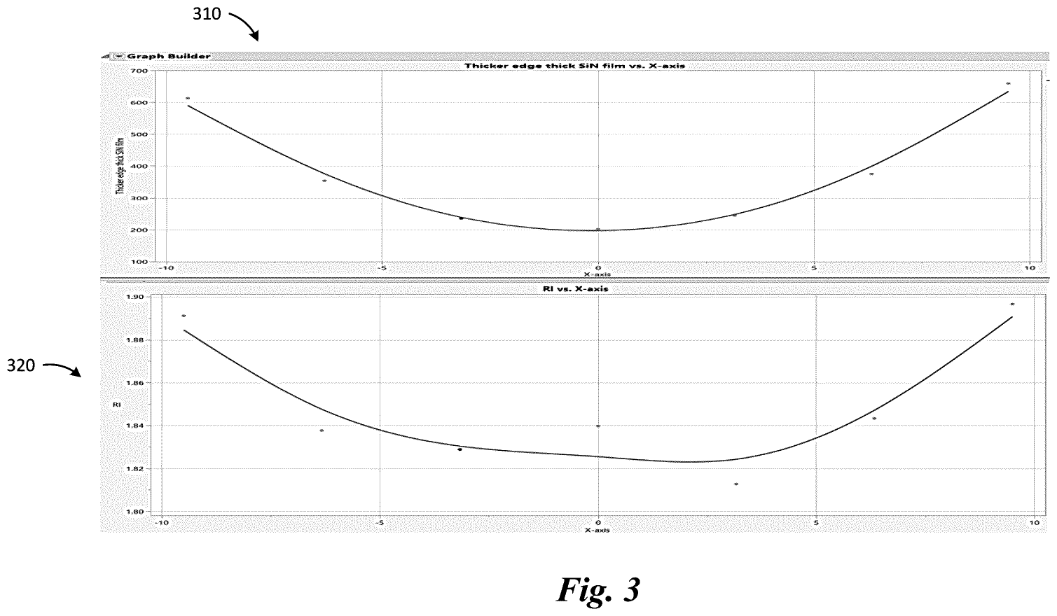

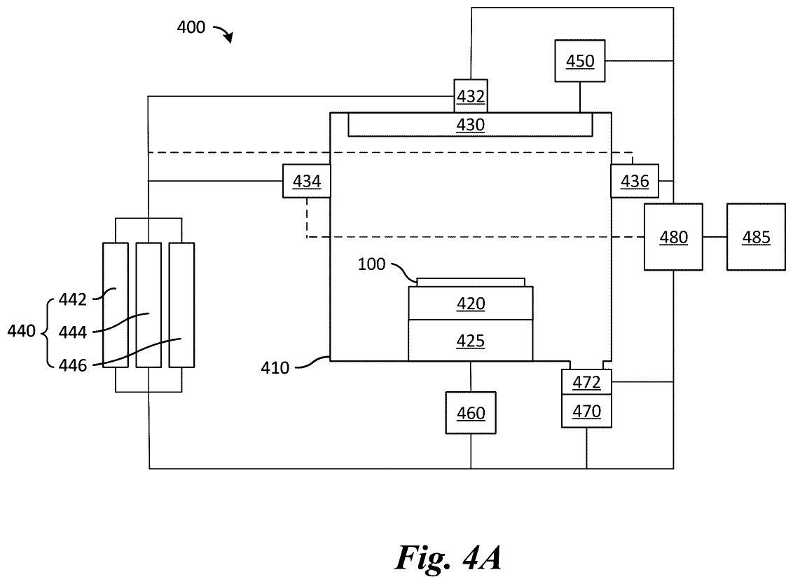

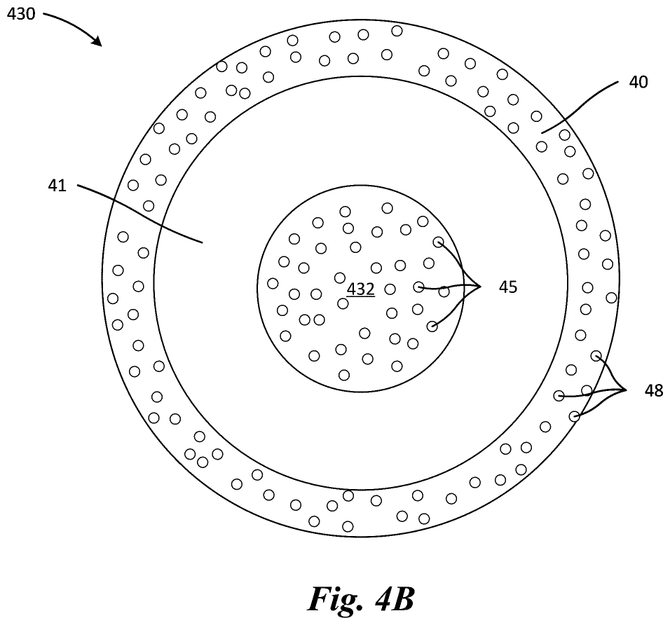

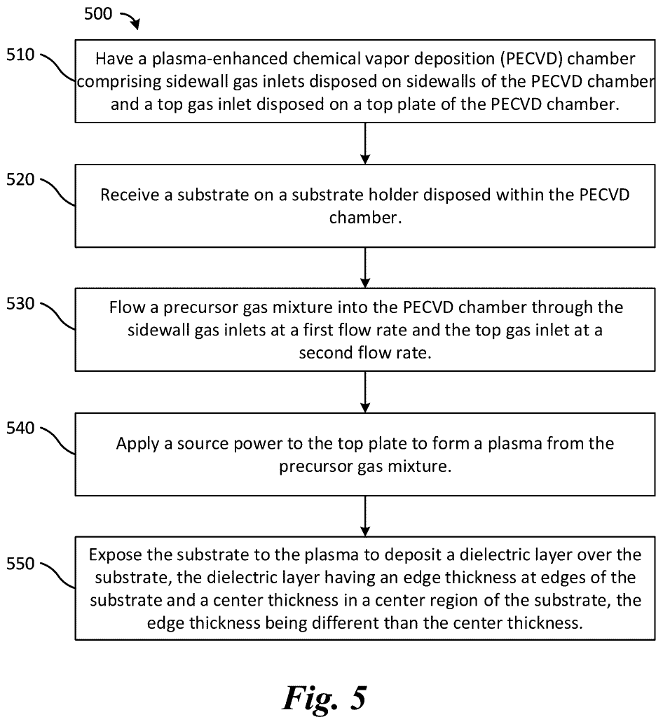

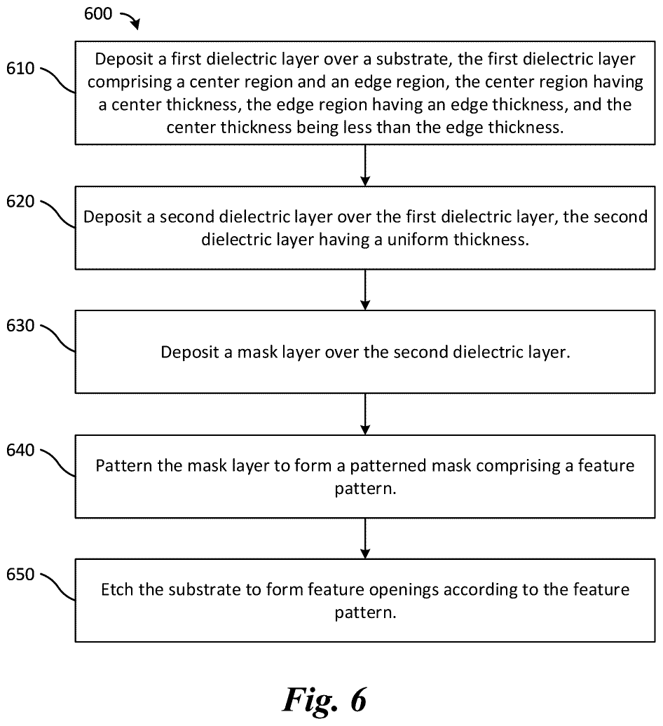

Embodiments provided below describe various methods, apparatuses and systems of processing a substrate, and in particular, to methods, apparatuses, and systems for depositing a material with controlled thickness profiles over the substrate. The following description describes the embodiments. FIGS. 1A-1F are used to describe various steps of a method of processing a substrate by depositing a variable thickness layer which may be used to prevent over-etching of edge regions (or a bevel edge) of the substrate. FIG. 2 illustrates an alternative embodiment of the step illustrated in FIG. 1B where the variable thickness layer is thicker in a center region of the substrate and thinner in edge regions of the substrate. Two plots illustrating properties of the variable thickness layer deposited using the embodiment methods of this disclosure are described using FIG. 3. An example plasma-enhanced chemical vapor deposition (PECVD) system which may be configured to deposit a variable thickness layer according to embodiment methods of this disclosure is described using FIG. 4A. A gas shower head which may be used as a top plate in the PECVD system of FIG. 4A is described using FIG. 4B. And FIGS. 5-6 are flowcharts used to describe two other example embodiment methods of processing a substrate by depositing a variable thickness layer using a PECVD system.

FIGS. 1A-1F are cross-sectional views of a substrate 100 illustrating various steps of a method of processing the substrate 100 by depositing a layer with a variable thickness throughout to improve etch protection in particular regions of the substrate 100. Specifically, the embodiment method illustrated in FIGS. 1A-1F may protect edge regions of the substrate 100 from over etch, and consequently increase product yield.

FIG. 1A illustrates a cross-sectional view of a substrate structure in accordance with one or more embodiments of the present disclosure. The substrate structure comprises a substrate 100 having a substrate base 102. In various embodiments, the substrate 100 may be a semiconductor wafer, such as a silicon wafer, a germanium wafer, or a compound semiconductor wafer. In an embodiment, the substrate 100 is a 300 mm diameter silicon wafer. In other embodiments, the substrate 100 may have different diameters, such as 200 mm.

The substrate base 102 may comprise various materials depending on the intended application. In one or more embodiments, the substrate base 102 is made of a semiconductor material, such as silicon, germanium, or an III-V compound semiconductor. In an embodiment, the substrate base 102 is single-crystal silicon. The substrate base 102 may be doped or undoped, depending on the desired electrical properties for the final device. Additionally, the substrate base 102 comprises a bevel 103 (or edge) where the substrate base 102 changes shape before terminating at the outer edge. In an embodiment where the substrate 100 is a circular wafer, the bevel 103 (or edge) completely surrounds the substrate base 102.

In various embodiments, the substrate 100 may comprise additional layers or structures not shown in FIG. 1A. For example, the substrate 100 may comprise buried oxide layers, epitaxial layers, or other semiconductor structures formed prior to the deposition of subsequent layers. In an embodiment, the substrate 100 may comprise partially fabricated integrated circuits or other devices formed upon or within the substrate base 102.

The thickness of the substrate 100 may vary depending on the specific application and manufacturing process. In one or more embodiments, the substrate 100 has a thickness in the range of about 500 μm to about 750 μm. However, thinner or thicker substrates may be used in various embodiments.

The substrate 100 comprises a top surface and a bottom surface, with the top surface being the surface on which subsequent layers are deposited. In various embodiments, the top surface of the substrate 100 may be planarized or otherwise prepared to provide a suitable surface for subsequent processing steps. For example, the top surface of the substrate 100 may be planarized through a conventional chemical mechanical planarization (CMP) process.

FIG. 1B illustrates a cross-sectional view of the substrate structure after depositing a first dielectric layer 104 over the entire top surface of the substrate 100. In one or more embodiments, the first dielectric layer 104 is deposited such that the edge thickness (hₑ) is larger than the center thickness (h_{c}). This variable thickness profile is achieved through a plasma-enhanced chemical vapor deposition (PECVD) process using a PECVD system.

The PECVD system comprises a PECVD chamber with sidewall gas inlets and a top gas inlet disposed on a top plate of the chamber. In various embodiments, the sidewall gas inlets flow a precursor gas mixture at a different rate than the top gas inlet, resulting in the non-uniform thickness profile of the first dielectric layer 104. By adjusting the flow rates of the sidewall gas inlets in contrast with the top gas inlet, the thickness profile may be controlled for the first dielectric layer 104. In the embodiment illustrated in FIG. 1B, sidewall gas inlets flowed the precursor gas mixture into the PECVD chamber faster than the top gas inlet (the top gas inlet disposed over a center region of the substrate 100), and consequently deposited the first dielectric layer 104 comprising an edge-thick thickness profile.

In one or more embodiments, the first dielectric layer 104 may comprise various materials. In an embodiment, the first dielectric layer 104 is silicon nitride (SiN). In other embodiments, the first dielectric layer 104 may be silicon oxide (SiO₂), silicon oxynitride (SiON), silicon carbide (SiC), silicon oxycarbide (SiOC), or combinations of these. The choice of material for the first dielectric layer 104 may depend on factors such as the desired etch selectivity, dielectric constant, and compatibility with subsequent processing steps.

The precursor gas mixtures used to deposit the first dielectric layer 104 may vary depending on the desired material and deposition conditions. In an embodiment where the first dielectric layer 104 is silicon nitride, the precursor gas mixture may comprise silane (SiH₄) and ammonia (NH₃). In other embodiments, the precursor gas mixture may comprise silane (SiH₄) and nitrogen (N₂), dichlorosilane (SiH₂Cl₂) and ammonia (NH₃), hexachlorodisilane (Si₂Cl₆) and ammonia (NH₃), tetraethyl orthosilicate (TEOS) and oxygen (O₂) for silicon oxide deposition, or trimethylsilane ((CH₃)₃SiH) and ammonia (NH₃) for silicon carbide deposition. In further embodiments, the precursor gas mixture may comprise SiCl₄, or SiF₄. In various embodiments, additional gases such as hydrogen (H₂), argon (Ar), helium (He), or nitrogen (N₂) may be added to the precursor gas mixture as carrier gases or to modify plasma characteristics used to deposit the variable thickness first dielectric layer 104.

The flow rates of the precursor gases through the sidewall gas inlets and the top gas inlet are controlled to achieve the desired thickness profile. In an embodiment, the flow rate through the sidewall gas inlets is higher than the flow rate through the top gas inlet, resulting in a higher deposition rate at the edges of the substrate 100.

The thickness difference between he and he may vary depending on the specific application and subsequent processing specifications. In one or more embodiments, the ratio of he to he may range from about 1.2:1 to about 3:1. In an embodiment, he is approximately 700 Å while he is approximately 200 Å, resulting in a ratio of about 3.5:1.

The non-uniform thickness profile of the first dielectric layer 104 serves to protect the edges of the substrate 100 during subsequent processing steps, particularly during through-silicon via (TSV) etching processes. This edge-thick profile helps prevent over-etching at the substrate edges, reducing defects and improving overall yield in the manufacturing process.

FIG. 1C illustrates a cross-sectional view of the substrate structure after depositing a second dielectric layer 106 over the first dielectric layer 104. In one or more embodiments, the second dielectric layer 106 is deposited through conventional plasma-enhanced chemical vapor deposition (PECVD) processes, resulting in a more uniform thickness across the substrate surface compared to the first dielectric layer 104. Additionally, the second dielectric layer 106 may be deposited over the substrate 100 within the center region without significant overlap into the edge regions of the substrate 100. Other embodiments may deposit the second dielectric layer 106 (and any other subsequent layer) over the edge regions as well.

The second dielectric layer 106 may comprise various materials depending on the specific specifications of the device being fabricated. In an embodiment, the second dielectric layer 106 is an oxide layer, specifically silicon dioxide (SiO₂). In other embodiments, the second dielectric layer 106 may comprise alternative materials, including silicon oxynitride (SiON), silicon nitride (Si₃N₄), lanthanum oxide (La₂O₃), low-k dielectric materials, such as carbon-doped silicon oxide (SiOC), high-k dielectric materials, such as hafnium oxide (HfO₂) or zirconium oxide (ZrO₂), aluminum oxide (Al₂O₃), tantalum oxide (Ta₂O₅), The choice of material for the second dielectric layer 106 may depend on factors such as the desired dielectric constant, etch selectivity relative to the first dielectric layer 104, thermal stability, and compatibility with subsequent processing steps.

In various embodiments, the thickness of the second dielectric layer 106 may range from about 500 Å to about 10,000 Å, depending on the specific application and design specifications. The deposition process for the second dielectric layer 106 may be optimized to achieve good step coverage over the underlying topography created by the variable-thickness first dielectric layer 104.

For the deposition of a silicon dioxide second dielectric layer 106, the PECVD process may use precursor gases such as silane (SiH₄) and nitrous oxide (N₂O), or tetraethyl orthosilicate (TEOS) and oxygen (O₂), or TEOS and ozone. In embodiments where alternative materials are used, the precursor gases may be adjusted accordingly. For example, silicon nitride deposition may use silane (SiH₄) and ammonia (NH₃), while a low-k dielectric may use organosilane precursors.

The deposition of the second dielectric layer 106 serves multiple purposes in the overall fabrication process. It may act as an additional insulating layer, a diffusion barrier, or a protective layer for subsequent processing steps. In one or more embodiments, the combination of the first dielectric layer 104 and the second dielectric layer 106 forms a dielectric stack that provides enhanced protection for the substrate edges during subsequent etching processes, such as through-silicon via (TSV) formation.

The uniformity of the second dielectric layer 106, in contrast to the variable thickness of the first dielectric layer 104, allows for more consistent and predictable behavior during subsequent patterning and etching steps across the entire substrate surface.

FIG. 1D illustrates a cross-sectional view of the substrate structure after depositing a mask layer 108 over the second dielectric layer 106. In one or more embodiments, the mask layer 108 is deposited through a suitable method to form a soft mask after subsequent patterning steps.

The deposition method for the mask layer 108 may vary depending on the specific material used and the desired characteristics of the resulting mask. In various embodiments, the deposition method may comprise spin coating, chemical vapor deposition (CVD), plasma-enhanced chemical vapor deposition (PECVD), or physical vapor deposition (PVD) techniques.

Soft masks are typically organic materials that can be easily patterned and removed after serving their purpose in the etching process. In one or more embodiments, the mask layer 108 may comprise different materials suitable for forming a soft mask, such as photoresist, bottom anti-reflective coating (BARC), silicon anti-reflective coating (Si-ARC), optical planarizing layer (OPL), spin-on carbon (SOC), spin-on glass (SOG), or an organic planarization layer. In various embodiments, the mask layer 108 is a photoresist material applied through a spin coating process.

The thickness of the mask layer 108 may vary depending on the specific material used and the specifications of subsequent etching processes. In various embodiments, the thickness may range from about 500 Å to about 30,000 Å.

In one or more embodiments, the mask layer 108 may consist of a single material layer. In other embodiments, it may comprise multiple layers, such as a combination of BARC and photoresist, to enhance the masking capabilities or improve the patterning process.

The selection of the mask layer 108 material and its deposition method may depend on factors such as the desired resolution of the subsequent patterning process, etch selectivity with respect to underlying layers, compatibility with the photolithography process, and ease of removal after etching.

The mask layer 108 serves as a template to be patterned in subsequent steps to define the locations where features, such as through-silicon vias (TSVs), will be formed. The use of a soft mask allows for easier removal after the etching process, potentially reducing the complexity of post-etch cleaning steps.

FIG. 1E illustrates a cross-sectional view of the substrate structure after patterning the mask layer 108 to form the patterned mask 110. The patterning process defines the feature pattern that will be transferred to the underlying layers in subsequent etching steps.

In one or more embodiments, the patterning of the mask layer 108 may be accomplished through various methods, depending on the type of mask material used and the desired feature size and density. In various embodiments, the patterning method may be a photolithography method (exposing the mask layer 108 to light through a photomask), an extreme ultra-violet (EUV) photolithography, other photolithography methods, an immersion method, an electron beam lithography (EBL) method, a nanoprint lithography method, or a directed self-assembly (DSA) method.

In various embodiments, the feature pattern of the patterned mask 110 may comprise an array of openings corresponding to the locations where through-silicon vias (TSVs) or other high aspect ratio features will be formed. The size and shape of these openings may vary depending on the specific application and design specifications.

The patterned mask 110 serves as a template for subsequent etching processes. The quality of the patterned mask 110, including feature resolution, edge definition, and uniformity across the substrate, directly impacts the quality of the final etched features. As illustrated in FIG. 1E, the first dielectric layer 104 covers the bevel edge (or edge region) of the substrate 100, and may protect the edge regions during the subsequent etching step described using FIG. 1F.

FIG. 1F illustrates a cross-sectional view of the substrate structure after performing a suitable etch process to transfer the feature pattern of the patterned mask 110 to the substrate 100, forming feature openings 112. The etch process selectively removes material from the exposed areas of the second dielectric layer 106, the first dielectric layer 104, and the substrate base 102 to create the desired features.

In various embodiments, the feature openings 112 may represent different structures depending on the specific application and device specifications. For example, the feature openings 112 may be through-silicon vias (TSVs) which may extend completely through the substrate base 102 or stop after reaching a certain depth, deep trench capacitors, MEMS structures, or isolation trenches.

For the TSV embodiment, the etch process to form the feature openings 112 may comprise multiple steps such as a dielectric etch which is an initial etch step removing the exposed portions of the second dielectric layer 106 and the first dielectric layer 104. The etch process may further comprise a silicon etch performed after the dielectric etch, such as a Bosch process or a continuous etch process. The silicon etch forms high aspect ratio openings (such as the feature openings 112) in the substrate base 102.

The etch process is optimized to achieve the desired depth, profile, and uniformity of the feature openings 112 across the substrate 100. In one or more embodiments, the depth of the TSVs may range from about 20 μm to about 350 μm, with aspect ratios (depth to width ratio) exceeding 10:1.

The variable thickness of the first dielectric layer 104 protects the edges of the substrate 100 from over-etching during the formation of the feature openings 112. This protection mechanism is achieved through the increased thickness (hₑ) of the first dielectric layer 104 at the substrate edges, which provides an additional etch buffer compared to the center region. The protections may also be enabled through etch time compensation, and as the etch process progresses, the thicker dielectric at the edges takes longer to etch through, which effectively reduces the silicon etch time at the substrate edges compared to the center. And consequently, the protection of the bevel edge of the substrate 100 by the variable thickness of the first dielectric layer 104 reduces edge defects, and improves die yield in the edge regions of the substrate 100.

For example, by the time the etch process reaches the substrate material at the edges, the center and main body of the substrate 100 have already been etched to the desired depth. This prevents over-etching and reduces the likelihood of edge defects such as chipping or cracking. The protection offered by the variable thickness first dielectric layer 104 helps maintain the integrity of devices near the substrate edges, potentially improving overall yield.

In various embodiments, the etch chemistry and parameters may be adjusted to achieve high selectivity between the mask material, dielectric layers, and the substrate material. This selectivity, combined with the variable thickness of the first dielectric layer 104, ensures that the feature openings 112 are formed with the desired depth and profile while minimizing damage to the substrate edges.

After the etch process, the patterned mask 110 may be removed using suitable stripping or ashing processes. In one or more embodiments, additional post-etch treatments may be performed to clean the feature openings 112, remove etch residues, or prepare the surfaces for subsequent processing steps such as barrier layer deposition or metal filling in the case of TSVs. Other embodiments may benefit through a different embodiment than an edge-thick first dielectric layer. For example, other embodiments may utilize a center-thick first dielectric layer, such as described using FIG. 2 below.

FIG. 2 illustrates an alternative cross-sectional view of the substrate structure after depositing a first dielectric layer 204 over the entire top surface of the substrate 100. In contrast to FIG. 1B, this embodiment shows a first dielectric layer 204 where the center thickness (h_{c}) is greater than the edge thickness (hₑ). This alternative deposition profile provides different advantages in subsequent processing steps.

In one or more embodiments, the first dielectric layer 204 is deposited using a modified plasma-enhanced chemical vapor deposition (PECVD) process. The PECVD system is configured to achieve a higher deposition rate at the center of the substrate compared to the edges. This non-uniform deposition is accomplished through careful control of process parameters and gas flow dynamics within the PECVD chamber.

The PECVD system may comprise a top plate positioned above the substrate, the top plate comprising a top gas inlet, and sidewalls of the PECVD system comprising sidewall gas inlets. In various embodiments, the gas flow rates, RF power distribution, and other process parameters are adjusted to create a center-thick deposition profile. For example, the precursor gas mixture may be introduced with a higher flow rate through the top gas inlet compared to the sidewall gas inlets.

The material composition of the first dielectric layer 204 may be similar to that described for the first dielectric layer 104 in FIG. 1B. In an embodiment, the first dielectric layer 204 is silicon nitride (SiN). In other embodiments, it may be silicon oxide (SiO₂), silicon oxynitride (SiON), silicon carbide (SiC), or other suitable dielectric materials.

The center-thick profile of the first dielectric layer 204 serves different purposes compared to the edge-thick profile seen in FIG. 1B. For example, the thicker center region can help compensate for any pre-existing substrate bow or warpage, potentially improving the overall planarity of the substrate for subsequent processing steps. In some embodiments, the center-thick profile may help manage stress distribution across the substrate, potentially reducing the risk of wafer warpage during high-temperature processes. And in other embodiments, during subsequent etching steps, the thicker center region allows for longer etch times in the center of the substrate, which can be advantageous for certain etch profiles or when dealing with etch rate non-uniformities. And in processes involving chemical-mechanical planarization (CMP), the center-thick profile can provide additional material in high-removal rate areas, potentially improving overall planarization results.

The thickness difference between he and he may vary depending on the specific application and subsequent processing specifications. In one or more embodiments, the ratio of h_{c} to hₑ may range from about 1.2:1 to about 3:1.

This alternative deposition profile of the first dielectric layer 204 offers flexibility in process integration, allowing for optimization of subsequent steps such as etching, CMP, or stress management. The choice between the edge-thick profile (FIG. 1B) and the center-thick profile (FIG. 2) may depend on the specific device specifications, process sensitivities, and overall manufacturing strategy.

In various embodiments, the methods described using FIGS. 1A-1F, and FIG. 2 are implemented without a clamp ring or a focus ring. As a result, the methods have the additional benefits of not biasing a focus ring (which reduces the amount of power consumed by the methods), and not implementing routine maintenance and cleaning of the focus ring or clamp ring (which reduces maintenance costs, and downtime for maintenance and cleaning).

Consequently, variable thickness layers may be deposited without using focus rings or clamp rings.

FIG. 3 illustrates a first plot 310 of film thickness compared to radial distance from the center of the substrate for the layer with variable thickness, and a second plot 320 of refractive index (RI) compared to radial distance from the center of the substrate for the layer with variable thickness. The y-axis of the first plot 310 shows a film thickness (in angstroms) of the dielectric layer of variable thickness (specifically, a SiN layer) deposited using the methods described in this disclosure. The x-axis of the first plot 310 and the second plot 320 is the radial distance from the center of the substrate with the dielectric layer of variable thickness, where 0 corresponds to the center of the substrate. And the y-axis of the second plot 320 shows the refractive index (RI) of the dielectric layer with variable thickness, which may indicate the quality of the dielectric layer.

As illustrated by the first plot 310, the edges of the substrate have an edge thickness of approximately 3 times a center thickness of the center region of the substrate, which corresponds to an edge thick embodiment. In other embodiments, the flow rates of precursor gas mixture through the top gas inlet and the sidewall gas inlets into a PECVD chamber may be further altered such that the ratio of the edge thickness to the center thickness is between 1.5:1 and 3.5:1. And in further embodiments, the flow rates may be altered to form a center region thick embodiment, where the ratio of the edge thickness to the center thickness of the dielectric layer is between 1:1.5 and 1:3.5. The second plot 320 shows good control of film deposition through the RI in comparison between the edge and center regions of the substrate. A PECVD system capable of implementing the method of this disclosure to deposit a variable thickness dielectric layer may be described using the system illustrated in FIG. 4A.

FIG. 4A illustrates a schematic diagram of a plasma-enhanced chemical vapor deposition (PECVD) system 400 that may be used to deposit the first dielectric layer 104 with variable thickness, as described in previous figures. The PECVD system 400 comprises several components designed to achieve precise control over the deposition process.

The PECVD system 400 comprises a PECVD chamber 410 which houses the main deposition components. Within the PECVD chamber 410, a substrate holder 420 is positioned to support the substrate 100 during the deposition process. The substrate holder 420 comprises a heater 425 to control the temperature of the substrate during deposition. In an embodiment, the substrate holder 420 comprises a resistive heater, where the heater 425 is the resistive heater.

At the top of the PECVD chamber 410 is a top plate 430. The top plate 430 comprises a top gas inlet 432 for introducing precursor gases into the PECVD chamber 410. Additionally, the PECVD chamber 410 comprises a first sidewall gas inlet 434 and a second sidewall gas inlet 436, positioned on sidewalls of the PECVD chamber 410 to allow for differential gas flow between the center and edge regions of the substrate 100. Though the PECVD system 400 illustrated in FIG. 4A illustrates only a first and second sidewall gas inlet (434, 436), other embodiments comprising even more sidewall gas inlets disposed throughout the sidewalls of the PECVD chamber 410 are also possible.

The gas delivery of the PECVD system 400 is controlled by a gas delivery system 440. This system manages the flow of various gases, such as a first precursor gas 442, a second precursor gas 444, and a purge gas 446. In one or more embodiments, these gases are combined to form the precursor gas mixture used for depositing the first dielectric layer 104. Additionally, the various first precursor gas 442 and second precursor gas 444 may comprise the various gases described above for the precursor gas mixture embodiments in FIGS. 1A-1F. In various embodiments, the purge gas 446 may be an inert gas used to purge the PECVD chamber 410 throughout various steps of the deposition process.

To generate the plasma for the enhanced chemical vapor deposition, the PECVD system 400 comprises a power source 450. This power source may be an RF generator or, in some embodiments, a microwave generator coupled to an antenna (such as a radial line slot antenna (RLSA)) disposed on the top plate 430. In various embodiments, the power source may be capable of supplying a source power between 500 W and 5000 W.

The temperature of the deposition process may be regulated by a temperature control system 460, which works in conjunction with the heater 425 to maintain the desired substrate temperature throughout the deposition. In various embodiments, the substrate holder 420 may be any suitable substrate holder known in the art capable of holding the substrate 100 during the embodiment methods of this disclosure.

To control the pressure within the PECVD chamber 410, the PECVD system 400 comprises a vacuum pump 470 connected to the PECVD chamber 410 through a valve 472. This setup allows for precise control of the chamber pressure during the deposition process.

The entire PECVD system 400 may be managed by a controller 480, which is connected to a memory 485. The controller 480 coordinates the operation of all system components, while the memory 485 stores process recipes, parameters, and other relevant data. The controller 480 and the memory 485 may be any suitable conventional device known in the art and capable of performing the functions described above.

In one or more embodiments, the PECVD system 400 is used to deposit the first dielectric layer 104 with variable thickness. This is achieved by using different flow rates for the precursor gas mixture through the sidewall gas inlets (434 and 436) compared to the top gas inlet 432. Specifically, a first flow rate is used for the sidewall gas inlets, while a second, different flow rate is used for the top gas inlet. This differential gas flow, controlled by the gas delivery system 440, enables the creation of a thickness gradient in the deposited first dielectric layer 104. As an example, in some embodiments, the second flow rate may be zero and the first flow rate is flowing the precursor mixture such that only the sidewall gas inlets (434 and 436) are flowing the precursor gas mixture into the PECVD chamber 410.

In an embodiment, the power source 450 comprises a microwave generator coupled with a Radial Line Slot Antenna (RLSA). The RLSA is designed to efficiently and uniformly couple microwave energy into the PECVD chamber 410, creating a high-density, low-temperature plasma. In a microwave PECVD (MW PECVD) embodiment, the top plate 430 may comprise quartz to further enable higher efficiency coupling of the microwave power to the precursor gas mixture to form the plasma used to deposit the variable thickness dielectric layer.

By carefully controlling the gas flow rates through the different inlets, the plasma characteristics, substrate temperature, and chamber pressure, the PECVD system 400 can deposit the first dielectric layer 104 with a precisely controlled variable thickness profile. This variable thickness can be tailored to be either edge-thick (as shown in FIG. 1B) or center-thick (as shown in FIG. 2), depending on the specific process specifications and the desired protection for subsequent etching steps. Other embodiments may use a capacitively coupled plasma (CCP) embodiment, or an inductively coupled plasma (ICP) embodiment for the PECVD system 400.

In various embodiments, the PECVD system 400 may be used to deposit a variable thickness layer without using a focus ring and a clamp ring. As a result, embodiments that do not use a focus ring and a clamp ring have the additional benefits of not using a bias to operate the focus ring (thus, lowering power consumption of the PECVD system 400), and not implementing routine maintenance or cleaning of the focus ring or clamp ring (thus, reducing equipment maintenance costs and reducing general equipment costs).

In another embodiment, the top plate 430 may be a gas shower head comprising various concentric rings, each concentric ring comprising a plurality of gas inlets. In the gas shower head embodiment, the gas flow rates through the various concentric rings may be individually controlled to further enhance the variable thickness deposition capabilities of the PECVD system 400. For example, an innermost ring of the gas shower head may have a much lower flow rate in comparison to an outermost ring of the gas shower head. And as a consequence, the different flow rates for the concentric rings enable the deposition of an edge-thick (or variable thickness) dielectric layer over the substrate 100. A gas shower head embodiment for the top plate 430 is described using FIG. 4B below.

FIG. 4B is a schematic diagram of an embodiment of the top plate 430 where the top plate 430 is a gas shower head. The top plate 430 is a gas shower head comprising a concentric ring 40 around the top gas inlet 432 disposed in the center of the top plate 430. A center region 41 is disposed between the top gas inlet 432 and the concentric ring 40. In an embodiment, the concentric ring 40 may be a gas ring comprising the sidewall gas inlets (434 and 436). In further embodiments, the center region 41 may comprise additional concentric rings, such as embodiments with as few as two concentric rings to embodiments with as many as ten concentric rings.

The concentric ring 40 comprises a first plurality of gas inlets 48. The top gas inlet 432 comprises a second plurality of gas inlets 45. The pluralities of gas inlets (45 and 48) may be controlled such that each plurality of gas inlets flows the precursor gas mixture into the PECVD chamber 410 at a different flow rate. For example, the top gas inlet 432 may flow the precursor gas mixture through the second plurality of gas inlets 45 at a different flow rate than the first plurality of gas inlets 48 of the concentric ring 40. As a result, the gas shower head embodiment for the top plate 430 in FIG. 4B may be used to deposit a variable thickness layer in accordance with the methods of this disclosure. In other embodiments comprising additional concentric rings with their own pluralities of gas inlets in the center region 41, the flow rates for each concentric ring may be independently controlled to further enhance the variable deposition capabilities of the top plate 430.

FIGS. 5-6 are flowcharts illustrating example methods of processing a substrate in accordance with embodiments of the disclosure. The methods of FIGS. 5-6 may be combined with other methods and performed using the systems and apparatuses as described herein. For example, the methods of FIGS. 5-6 may be implemented in the PECVD system 400 of FIG. 4A. Although shown in a logical order, the arrangement and numbering of the steps of FIGS. 5-6 are not intended to be limiting.

Referring to FIG. 5, step 510 of a method 500 for processing a substrate has a plasma-enhanced chemical vapor deposition (PECVD) chamber comprising sidewall gas inlets disposed on sidewalls of the PECVD chamber and a top gas inlet disposed on a top plate of the PECVD chamber. In various embodiments, the PECVD chamber may be the PECVD chamber 410 of the PECVD system described using FIG. 4A. In similar embodiments, the sidewall gas inlets, the top gas inlet, and the top plate may be the sidewall gas inlets (434, 436), the top gas inlet 432, and the top plate 430 of FIG. 4A.

The method 500 receives the substrate on a substrate holder disposed within the PECVD chamber in step 520. In various embodiments, the substrate may be the substrate 100 described in FIG. 1A, where the substrate 100 is ready to be processed in accordance with the method of this disclosure, such as the method 500. In embodiments, the substrate holder may be any suitable holder for holding the substrate during the processing, such as the substrate holder 420 of the PECVD system 400 described using FIG. 4A.

Step 530 of the method 500 flows a precursor gas mixture into the PECVD chamber through the sidewall gas inlets at a first flow rate and the top gas inlet at a second flow rate. And the method 500, in step 540, applies a source power to the top plate to form a plasma from the precursor gas mixture. The precursor gas mixture may be as described in either FIG. 1B or FIG. 4A, and the flow rates may be as similarly described for those same figures. Further, the flow rates may be adjusted depending on the variable thickness desired. For example, an edge thick embodiment may flow the precursor gas mixture at the first flow rate through the sidewall gas inlets faster than the second flow rate through the top gas inlet. In another embodiment, the second flow rate may be faster than the first flow rate, which may form a layer with a variable thickness such that the center thickness is larger than the edge thickness (such as illustrated in FIG. 2).

In various embodiments, the plasma may be formed using a microwave source power applied to an antenna, such as an RLSA disposed on or above the top plate of the PECVD system. In those embodiments, the plasma is formed through the coupling of the RLSA with the precursor gas mixture within the PECVD chamber. In other embodiments, the plasma may be formed using radio frequency (RF) power supplied to the top plate to form a capacitively coupled plasma (CCP). Inductively coupled plasmas (ICPs) may also be used in other embodiments.

Step 550 of the method 500 exposes the substrate to the plasma to deposit a dielectric layer over the substrate. The dielectric layer has an edge thickness at edges of the substrate and a center thickness in a center region of the substrate, where the edge thickness is different than the center thickness. In various embodiments, the center thickness may be larger than the edge thickness (such as the first dielectric layer 204 illustrated in FIG. 2). In other embodiments, the center thickness may be smaller than the edge thickness, and the dielectric layer may be deposited thicker at the edges of the substrate to protect the bevel edges from over-etching in further processing steps (such as the first dielectric layer 104 illustrated in FIG. 1B). The dielectric layer may be the first dielectric layer 104 of FIG. 1B, and the method 500 may be the process performed to form the first dielectric layer 104 of FIG. 1B.

Now referring to FIG. 6, step 610 of a method 600 of processing a substrate deposits a first dielectric layer over the substrate. The first dielectric layer comprises a center region and an edge region, where the center region has a center thickness, and the edge region has an edge thickness. Further, the center thickness is less than the edge thickness. The substrate may be the substrate 100 of FIGS. 1A-1F. And the method 500 of FIG. 5 may be the deposition method used to deposit the first dielectric layer over the substrate. Further, the first dielectric layer may be the first dielectric layer 104 described in FIG. 1B. In an embodiment, step 610 of the method 600 may be the step illustrated in FIG. 1B. After, in step 620, the method 600 deposits a second dielectric layer over the first dielectric layer, the second dielectric layer having a uniform thickness.

Step 620 may perform another deposition process using a second precursor gas mixture to deposit the second dielectric layer with a uniform thickness (as opposed to the variable thickness of the first dielectric layer). For example, a PECVD system may be used to deposit the second dielectric layer. In various embodiments, the second dielectric layer may be the second dielectric layer 106 deposited similarly as described for FIG. 1C, and the second dielectric layer may be any suitable material as described for the second dielectric layer 106. In certain embodiments, a planarization process may be performed to planarize the second dielectric layer after step 620.

In step 630, the method 600 deposits a mask layer over the second dielectric layer. In various embodiments, the mask layer may be the mask layer 108 described in FIG. 1D, and deposited similarly. Additionally, the mask layer may be any suitable material for subsequently patterning and transferring a feature pattern to underlying layers of the substrate.

Step 640 of the method 600 patterns the mask layer to form a patterned mask comprising a feature pattern. In various embodiments, the patterned mask may be the patterned mask 110 of FIG. 1E, and the feature pattern may comprise a pattern for forming through-silicon vias (TSVs). The patterning may be performed through any suitable conventional patterning process, such as light exposure through a photomask onto photoresist.

Still referring to FIG. 6, step 650 of the method 600 etches the substrate to form feature openings according to the feature pattern. Step 650 may represent the step illustrated in FIG. 1F. In various embodiments, the feature openings may be the feature openings 112 of FIG. 1F. Further, the feature openings may be as described for the feature openings 112 of FIG. 1F, such as through-silicon vias.

The etching process in step 650 may be any suitable conventional etching process for forming the feature openings according to the feature pattern of the patterned mask. For example, in various embodiments, a reactive ion etch (RIE) process may be performed. As a benefit of the method 600, the variable thickness of the first dielectric layer having a larger thickness at the edges of the substrate prevents punch-through (or over-etch) into the substrate. And consequently, prevents die loss, or fabrication loss near edges of the substrate as a result of over-etching near the edges of the substrate and damaging underlying layers of devices being fabricated in the substrate.

In various embodiments, the method 600 may be the various steps illustrated and described using FIGS. 1A-1F. Both methods 500-600 enable edge protection near the edges of the substrate during etching processes, which increases device yield. Further, both methods 500-600 are more cost effective than conventional methods that use an edge clamp, and the methods 500-600 prevent other difficulties that result through the use of edge clamps to protect substrate edges during processing.

Example embodiments of the invention are described below. Other embodiments can also be understood from the entirety of the specification as well as the claims filed herein.

Example 1. A method for processing a substrate includes having a plasma-enhanced chemical vapor deposition (PECVD) chamber including sidewall gas inlets disposed on sidewalls of the PECVD chamber and a top gas inlet disposed on a top plate of the PECVD chamber. The method further includes receiving the substrate on a substrate holder disposed within the PECVD chamber, and flowing a precursor gas mixture into the PECVD chamber through the sidewall gas inlets at a first flow rate and the top gas inlet at a second flow rate. And the method further includes applying a source power to the top plate to form a plasma from the precursor gas mixture, and exposing the substrate to the plasma to deposit a dielectric layer over the substrate, where the dielectric layer has an edge thickness at edges of the substrate and a center thickness in a center region of the substrate, where the edge thickness is different from the center thickness.

Example 2. The method of example 1, where the source power is microwave power including a microwave frequency, the top plate includes quartz, and the source power is applied to a radial line slot antenna (RLSA) disposed on the top plate.

Example 3. The method of one of examples 1 or 2, where the first flow rate is faster than the second flow rate, the edge thickness is larger than the center thickness, and a thickness ratio of the edge thickness to the center thickness is between 1.5:1 and 3.5:1.

Example 4. The method of one of examples 1 to 3, where the first flow rate is slower than the second flow rate, the edge thickness is smaller than the center thickness, and a thickness ratio of the edge thickness to the center thickness is between 1:1.5 and 1:3.5.

Example 5. The method of one of examples 1 to 4, where the substrate includes a silicon wafer, the dielectric layer includes silicon nitride (SiN), and the precursor gas mixture includes silane (SiH₄), ammonia (NH₃), and nitrogen gas (N₂).

Example 6. The method of one of examples 1 to 5, where the precursor gas mixture includes at least one of silane (SiH₄), disilane (Si₂H₆), ammonia (NH₃), hydrogen gas (H₂), nitrogen gas (N₂), and nitrous oxide (N₂O).

Example 7. The method of one of examples 1 to 6, where the top plate is a gas shower head including a plurality of concentric rings, each concentric ring including a plurality of gas nozzles, where flow rates through each concentric ring may be controlled such that the dielectric layer is deposited with a variable thickness between the center region and the edges of the substrate.

Example 8. The method of one of examples 1 to 7, where the sidewall gas inlets include a first gas inlet and a second gas inlet disposed on opposite sidewalls of the PECVD chamber, and the substrate is spun about a center axis during the exposing to the plasma.

Example 9. The method of one of examples 1 to 8, further including controlling a temperature of the substrate holder to maintain the substrate at a predetermined temperature during the exposing the substrate to the plasma to deposit the dielectric layer.

Example 10. The method of one of examples 1 to 9, where the source power is applied at a power level between 500 W and 5000 W.

Example 11. The method of one of examples 1 to 10, further including holding the substrate on the substrate holder without a focus ring disposed around the substrate holder and without a clamp ring to hold the substrate.

Example 12. A method for processing a substrate includes depositing a first dielectric layer over the substrate, the first dielectric layer including a center region and an edge region, where the center region has a center thickness, where the edge region has an edge thickness, and where the center thickness is less than the edge thickness. The method further includes depositing a second dielectric layer over the first dielectric layer, where the second dielectric layer has a uniform thickness, and depositing a mask layer over the second dielectric layer. And the method further includes patterning the mask layer to form a patterned mask including a feature pattern, and etching the substrate to form feature openings according to the feature pattern.

Example 13. The method of example 12, where the substrate includes a silicon wafer, the first dielectric layer includes silicon nitride, the second dielectric layer includes silicon oxide, the mask layer includes a soft mask, and the feature openings include through-silicon vias (TSVs).

Example 14. The method of one of examples 12 or 13, further including performing a chemical mechanical polishing (CMP) process on the second dielectric layer before depositing the mask layer.

Example 15. The method of one of examples 12 to 14, where depositing the first dielectric layer includes flowing a precursor gas mixture into a plasma-enhanced chemical vapor deposition (PECVD) chamber through sidewall gas inlets at a first flow rate and a top gas inlet at a second flow rate, where the sidewall gas inlets are disposed on sidewalls of the PECVD chamber, and where the top gas inlet is disposed on a top plate of the PECVD chamber. And the depositing further includes applying a source power to the top plate to form a plasma from the precursor gas mixture, and exposing the substrate to the plasma to deposit the first dielectric layer over the substrate.

Example 16. The method of one of examples 12 to 15, where the first flow rate is faster than the second flow rate, and a thickness ratio of the edge thickness to the center thickness is between 1.5:1 and 3.5:1.

Example 17. A system for processing a substrate includes a substrate holder disposed within a plasma-enhanced chemical vapor deposition (PECVD) chamber, sidewall gas inlets disposed on sidewalls of the PECVD chamber, a top gas inlet disposed on a top plate of the PECVD chamber, a gas delivery system coupled to the sidewall gas inlets and the top gas inlet, the gas delivery system configured to supply a precursor gas mixture at controlled flow rates. The system further includes a vacuum pump coupled to the PECVD chamber through a gate valve, and a power source electrically coupled with the top plate. And the system further includes a controller coupled to the substrate holder, the sidewall gas inlets, the top gas inlet, the gas delivery system, the vacuum pump, the power source, and a memory storing instructions to be executed in the controller. The instructions, when executed, enable the controller to receive the substrate on the substrate holder, and flow the precursor gas mixture into the PECVD chamber through the sidewall gas inlets at a first flow rate and the top gas inlet at a second flow rate using the gas delivery system. The instructions, when executed further, enable the controller to apply, using the power source, a source power to the top plate to form a plasma from the precursor gas mixture. And the instructions, when executed further, enable the controller to expose the substrate to the plasma to deposit a dielectric layer over the substrate, where the dielectric layer has an edge thickness at edges of the substrate and a center thickness in a center region of the substrate, where the edge thickness is larger than the center thickness.

Example 18. The system of example 17, where the substrate holder is a resistive heater.

Example 19. The system of one of examples 17 or 18, where the controller is further configured to adjust the first flow rate and the second flow rate to control a thickness profile of the dielectric layer.

Example 20. The system of one of examples 17 to 19, where the precursor gas mixture includes silane (SiH₄), ammonia (NH₃), and nitrogen gas (N₂).

Example 21. The system of one of examples 17 to 20, where the top plate is a gas shower head including a plurality of concentric rings, each concentric ring including a plurality of gas nozzles, where flow rates through each concentric ring may be controlled such that the dielectric layer is deposited with a variable thickness between the center region and the edges of the substrate.

Example 22. The system of one of examples 17 to 21, where the top plate is quartz, the power source is a microwave generator, and the source power is microwave power including a microwave frequency.

Example 23. The system of one of examples 17 to 22, further including a radial line slot antenna (RLSA) disposed on the top plate and electrically coupled to the power source, where the RLSA is configured to couple the source power to the precursor gas mixture to form the plasma.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A method for processing a substrate, the method comprising:
having a plasma-enhanced chemical vapor deposition (PECVD) chamber comprising sidewall gas inlets disposed on sidewalls of the PECVD chamber and a top gas inlet disposed on a top plate of the PECVD chamber;
receiving the substrate on a substrate holder disposed within the PECVD chamber;
flowing a precursor gas mixture into the PECVD chamber through the sidewall gas inlets at a first flow rate and the top gas inlet at a second flow rate;
applying a source power to the top plate to form a plasma from the precursor gas mixture; and
exposing the substrate to the plasma to deposit a dielectric layer over the substrate, wherein the dielectric layer has an edge thickness at edges of the substrate and a center thickness in a center region of the substrate, wherein the edge thickness is different from the center thickness.

2. The method of claim 1, wherein the source power is microwave power comprising a microwave frequency, the top plate comprises quartz, and the source power is applied to a radial line slot antenna (RLSA) disposed on the top plate, and wherein the source power is applied at a power level between 500 W and 5000 W.

3. The method of claim 1, wherein the first flow rate is faster than the second flow rate, the edge thickness is larger than the center thickness, and a thickness ratio of the edge thickness to the center thickness is between 1.5:1 and 3.5:1.

4. The method of claim 1, wherein the first flow rate is slower than the second flow rate, the edge thickness is smaller than the center thickness, and a thickness ratio of the edge thickness to the center thickness is between 1:1.5 and 1:3.5.

5. The method of claim 1, wherein the substrate comprises a silicon wafer, the dielectric layer comprises silicon nitride (SiN), and the precursor gas mixture comprises at least one of silane (SiH₄), disilane (Si₂H₆), ammonia (NH₃), hydrogen gas (H₂), nitrogen gas (N₂), and nitrous oxide (N₂O).

6. The method of claim 1, wherein the top plate is a gas shower head comprising a plurality of concentric rings, each concentric ring comprising a plurality of gas nozzles, wherein flow rates through each concentric ring may be controlled such that the dielectric layer is deposited with a variable thickness between the center region and the edges of the substrate.

7. The method of claim 1, wherein the sidewall gas inlets comprise a first gas inlet and a second gas inlet disposed on opposite sidewalls of the PECVD chamber, and the substrate is spun about a center axis during the exposing to the plasma.

8. The method of claim 1, further comprising controlling a temperature of the substrate holder to maintain the substrate at a predetermined temperature during the exposing the substrate to the plasma to deposit the dielectric layer.

9. The method of claim 1, further comprising holding the substrate on the substrate holder without a focus ring disposed around the substrate holder and without a clamp ring to hold the substrate.

10. A method for processing a substrate, the method comprising:
depositing a first dielectric layer over the substrate, the first dielectric layer comprising a center region and an edge region, wherein the center region has a center thickness, wherein the edge region has an edge thickness, and wherein the center thickness is less than the edge thickness;
depositing a second dielectric layer over the first dielectric layer, wherein the second dielectric layer has a uniform thickness;
depositing a mask layer over the second dielectric layer;
patterning the mask layer to form a patterned mask comprising a feature pattern; and
etching the substrate to form feature openings according to the feature pattern.

11. The method of claim 10, wherein the substrate comprises a silicon wafer, the first dielectric layer comprises silicon nitride, the second dielectric layer comprises silicon oxide, the mask layer comprises a soft mask, and the feature openings comprise through-silicon vias (TSVs).

12. The method of claim 10, further comprising performing a chemical mechanical polishing (CMP) process on the second dielectric layer before depositing the mask layer.

13. The method of claim 10, wherein depositing the first dielectric layer comprises:
flowing a precursor gas mixture into a plasma-enhanced chemical vapor deposition (PECVD) chamber through sidewall gas inlets at a first flow rate and a top gas inlet at a second flow rate, wherein the sidewall gas inlets are disposed on sidewalls of the PECVD chamber, and wherein the top gas inlet is disposed on a top plate of the PECVD chamber;
applying a source power to the top plate to form a plasma from the precursor gas mixture; and
exposing the substrate to the plasma to deposit the first dielectric layer over the substrate.

14. The method of claim 13, wherein the first flow rate is faster than the second flow rate, and a thickness ratio of the edge thickness to the center thickness is between 1.5:1 and 3.5:1.

15-20. (canceled)

21. The method of claim 13, wherein the precursor gas mixture comprises silane (SiH₄), ammonia (NH₃), and nitrogen gas (N₂).

22. A method for depositing a dielectric layer over a substrate, the method comprising:
flowing a precursor gas mixture into a plasma-enhanced chemical vapor deposition (PECVD) chamber through sidewall gas inlets at a first flow rate and a top gas inlet at a second flow rate, wherein the sidewall gas inlets are disposed on sidewalls of the PECVD chamber, and wherein the top gas inlet is disposed on a top plate of the PECVD chamber;
applying a source power to the top plate to form a plasma from the precursor gas mixture; and
exposing the substrate to the plasma to deposit the dielectric layer over the substrate, wherein the top plate is a gas shower head comprising a plurality of concentric rings, each concentric ring comprising a plurality of gas nozzles, wherein flow rates through each concentric ring may be controlled such that the dielectric layer is deposited with a variable thickness.

23. The method of claim 22, wherein depositing the dielectric layer further comprises controlling a temperature of a substrate holder to maintain the substrate at a predetermined temperature during the exposing the substrate to the plasma.

24. The method of claim 23, wherein the substrate holder comprises a resistive heater.

25. The method of claim 22, wherein depositing the dielectric layer further comprises adjusting the first flow rate and the second flow rate to control a thickness profile of the dielectric layer during the flowing the precursor gas mixture.

26. The method of claim 22, wherein the source power is applied using a power source, wherein a radial line slot antenna (RLSA) couples the source power to the precursor gas mixture to form the plasma, and wherein the top plate is quartz, the power source is a microwave generator, and the source power is microwave power comprising a microwave frequency.
